(19) United States
(12) Patent Application Publication
(10) Pub. No.: US 2026/0269174 A1
(43) Pub. Date: Sep. 10, 2026

(54) Electron Microscope

(71) Applicant: Hitachi high-Tech Corporation, Minato-ku, Tokyo (JP)

(72) Inventors: Hiroki KAWAMOTO, Tokyo (JP); Takashi FUJII, Tokyo (JP); Toshie YAGUCHI, Tokyo (JP); Takeshi SATO, Tokyo (JP)

(21) Appl. No.: 19/160,914

(22) PCT Filed: May 25, 2023
(86) PCT No.: PCT/JP2023/019584

§ 371 Date: Aug. 29, 2025

(51) Int. Cl. H01J 37/20

(52) U.S. Cl. CPC H01J 37/20; H01J 2237/002; H01J 2237/022; H01J 2237/028

(57) ABSTRACT

To improve the performance of an electron microscope. As a section for improving the performance of an electron microscope, an electron microscope is used that includes: a sample stage; a first cold finger arranged on an upstream side of an optical axis with respect to the sample stage; a second cold finger arranged on a downstream side of the optical axis with respect to the first cold finger with the sample stage interposed therebetween; and a movable mechanism configured to move the first cold finger and the second cold finger in an insertion and removal direction with respect to the optical axis. Here, the movable mechanism is configured to change a solid angle at which a sample placement portion of the sample stage is covered by one or both of the first cold finger and the second cold finger.

### TECHNICAL FIELD

The present invention relates to an electron microscope, and in particular to an electron microscope equipped with a cold finger.

### BACKGROUND ART

In recent years, transmission electron microscopes (TEM) and scanning electron microscopes (SEM) have become known as devices for observing samples. During sample analysis using these electron microscopes, contamination adheres to the sample during observation. In this case, by using a cold finger cooled with liquid nitrogen or the like, the contamination can be adsorbed onto the cold finger rather than onto the sample.

PTL 1 (WO2015/41267) describes a scanning electron microscope equipped with an anti-contamination trap in which a cooling unit is cooled via a copper rod connected to a cooling tank.

### CITATION LIST

### Patent Literature

PTL 1: WO2015/41267A

### SUMMARY OF INVENTION

### Technical Problem

The adsorption efficiency of the cold finger improves as the distance between the cold finger and the sample decreases. However, if the cold finger is placed too close to the sample, problems such as limiting a tilt range of a holder holding the sample may occur. Therefore, depending on the shape and position of the cold finger, there is a risk that available analytical methods may be limited. Further, as core facility integration advances, there is a growing demand for a single device to support a wide variety of analytical methods.

The invention has been conceived to solve the above problems, and an object of the invention is to improve the performance of an electron microscope.

### Solution to Problem

An outline of a representative one among embodiments disclosed in the present application will be briefly described as follows.

An electron microscope according to an embodiment includes: a sample stage; a first cold finger arranged on an upstream side of an optical axis with respect to the sample stage; a second cold finger arranged on a downstream side of the optical axis with respect to the first cold finger with the sample stage interposed therebetween; and a movable mechanism configured to move the first cold finger and the second cold finger in an insertion and removal direction with respect to the optical axis. Here, the movable mechanism is configured to change a solid angle at which a sample placement portion of the sample stage is covered by one or both of the first cold finger and the second cold finger.

### Advantageous Effects of Invention

According to the invention, the performance of an electron microscope can be improved.

### BRIEF DESCRIPTION OF DRAWINGS

FIG. 1 is a schematic diagram illustrating an electron microscope according to Embodiment 1.

FIG. 2 is a schematic diagram illustrating a cooling unit constituting the electron microscope according to Embodiment 1.

FIG. 3 is a schematic diagram illustrating cold fingers and a sample stage constituting the electron microscope in Example 1 of Embodiment 1.

FIG. 4 is a schematic diagram illustrating the cold fingers and the sample stage constituting the electron microscope in Example 2 of Embodiment 1.

FIG. 5 is a schematic diagram illustrating the cold fingers and the sample stage constituting the electron microscope in Example 2 of Embodiment 1.

FIG. 6 is a schematic diagram illustrating the cold fingers and the sample stage constituting the electron microscope in Example 3 of Embodiment 1.

FIG. 7 is a schematic diagram illustrating cold fingers and the sample stage constituting an electron microscope in Example 4 of Embodiment 2.

FIG. 8 is a schematic diagram illustrating the cold fingers and the sample stage constituting the electron microscope in Example 5 of Embodiment 2.

FIG. 9 is a plan view illustrating cold fingers and the sample stage constituting an electron microscope in Example 6 of Embodiment 3.

FIG. 10 is a plan view illustrating the cold fingers and the sample stage constituting the electron microscope in Example 7 of Embodiment 3.

FIG. 11 is a schematic diagram illustrating a cold finger and a sample stage constituting an electron microscope in a comparative example.

### DESCRIPTION OF EMBODIMENTS

Hereinafter, embodiments of the invention will be described in detail with reference to the drawings. In all the drawings for describing the embodiments, members having the same function are denoted by the same reference numeral, and the repeated description thereof will be omitted. In the embodiments, the description of the same or similar parts will not be repeated in principle unless particularly necessary.

As used herein, an X direction (X axis) and a Y direction (Y axis) are orthogonal to each other, and both are directions along a horizontal plane. Here, a direction perpendicular to the X direction and the Y direction is referred to as a Z direction (Z axis) or an up-down direction.

### Embodiment 1

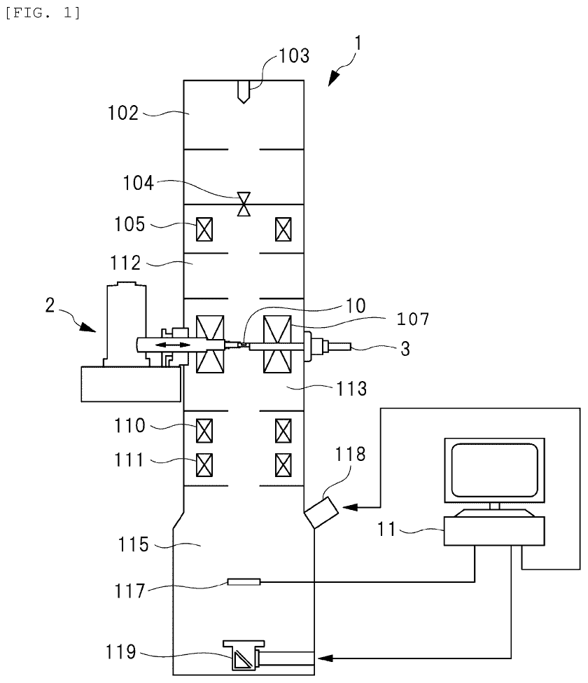

Hereinafter, an example of an electron microscope as an example will be described. A device including an insertable and removable cold finger according to the present embodiment is applicable to a transmission electron microscope (TEM) or a scanning transmission electron microscope (STEM). Here, a transmission electron microscope will be described as an example. FIG. 1 is a schematic diagram illustrating an electron microscope according to the present embodiment.

FIG. 1 illustrates a transmission electron microscope (TEM) 1 according to the present embodiment. The transmission electron microscope 1 includes an electron column 102. In the electron column 102, an electron gun 103, a gun valve 104, a condenser lens 105, an objective lens 107, an intermediate lens 110, and a projection lens 111 arranged in this order from top to bottom constitute an electron beam optical system. An intermediate chamber 112 is provided below the condenser lens 105, and a sample chamber 113 accommodating the objective lens 107 is provided below the intermediate chamber 112. A sample stage 3 can be inserted into and removed from the sample chamber 113. A sample 10 is placed on the sample stage 3. The sample 10 is, for example, a sample of carbon black or a semiconductor wafer. The term “insertion/removal” as used herein refers to insertion into or removal from an irradiation region of an electron beam emitted from the electron gun 103.

An observation chamber 115 is provided below the projection lens 111. In the observation chamber 115, a fluorescent plate 117 and a detector (imaging unit, camera) 119 are provided in this order from top to bottom. The detector (detector array) 119 is, for example, a camera including a charge coupled device (CCD) camera or a complementary metal oxide semiconductor (CMOS) image sensor. An electron diffraction pattern is projected onto the detector 119. A fluorescent plate detector array (imaging unit, camera) 118 for imaging the fluorescent plate 117 in the observation chamber 115 is provided on a side surface of the observation chamber 115.

A computer (control unit) 11 is installed outside the transmission electron microscope 1. The fluorescent plate 117 and the detector 119 are connected to the computer 11. A display unit (monitor) is connected to the computer 11. That is, the display unit is a display installed outside the transmission electron microscope 1. A cooling unit 2 including a cold finger that can be inserted into and removed from the sample chamber 113 is attached to the electron column 102.

The electron beam generated from the electron gun 103 is converged by the condenser lens 105 and emitted onto the sample 10. The electron beam transmitted through the sample 10 on the sample stage 3 is imaged by the objective lens 107 and enlarged by the intermediate lens 110 and the projection lens 111. The enlarged transmission image of the sample 10 is projected onto the fluorescent plate 117 or the detector 119. The transmission image projected on the fluorescent plate 117 is captured by the fluorescent plate detector array 118 and stored in the computer 11. Thus, a transmission image (high-magnification image (enlarged image) ) or an electron diffraction pattern (diffraction spot) projected on the detector 119 by the electron beam transmitted through the sample 10 is obtained.

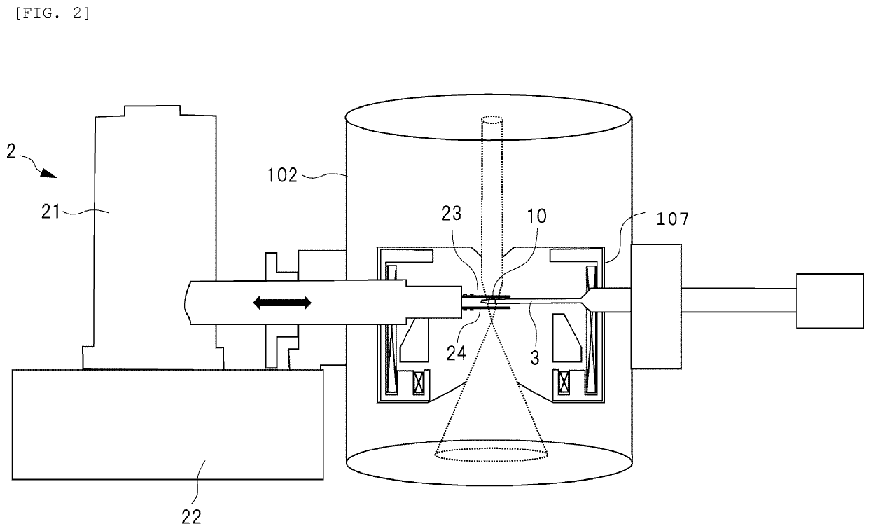

FIG. 2 is a schematic diagram illustrating a state in which cold fingers 23 and 24 that can be inserted into and removed from the electron column 102 in the present embodiment are inserted in an optical axis direction. FIG. 2 is a cross-sectional view.

The cooling unit 2 includes a dewar 21 capable of containing liquid nitrogen and a movable mechanism (movable portion) 22. The dewar 21 and the movable mechanism 22 are disposed outside the electron column 102. At an end portion of the movable mechanism 22 closer to the sample stage 3, the cold finger 23 and the cold finger 24 that are insertable and removable in the optical axis direction are provided as components of the cooling unit 2. The movable mechanism 22 has a function of moving a component in a radial direction of the electron column 102 with respect to the cylindrical electron column 102 extending in the up-down direction (Z direction), for example. Since the cooling unit 2 includes the movable mechanism 22, the cold finger 23 and the cold finger 24 can be inserted and removed with respect to the optical axis direction, and a solid angle of the sample 10 inside the objective lens 107 and on the sample stage 3 can be changed. That is, the movable mechanism 22 can move the cold fingers 23 and 24 in an insertion and removal direction with respect to the optical axis. By the above operation of the movable mechanism 22, the solid angle at which a sample placement portion 3a of the sample stage is covered by one or both of the cold fingers 23 and 24 can be changed.

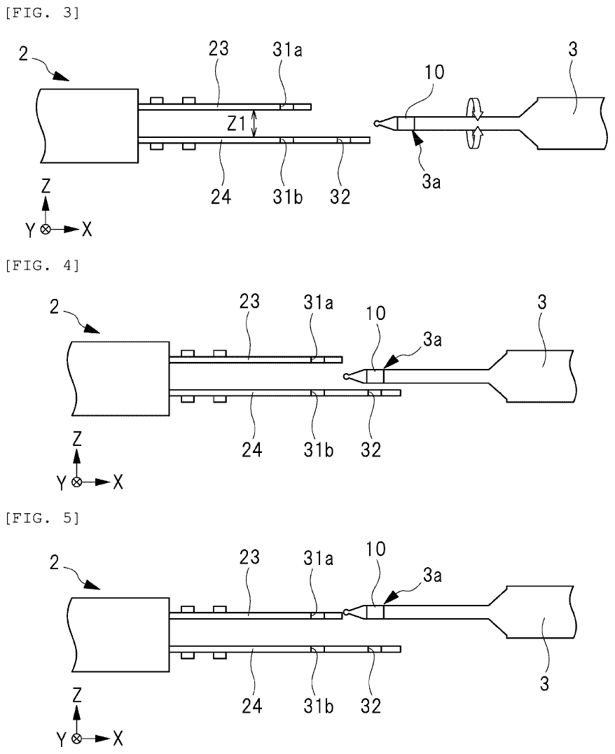

FIG. 3 illustrates a schematic diagram of a tip shape of the cold finger in the present embodiment. FIG. 3 is a partially cutaway side view of the cold finger and the sample stage. As illustrated in FIG. 3, the cold fingers 23 and 24 at least partially overlap each other in the Z direction (up-down direction). The Z direction is a direction along the optical axis. The optical axis direction in the present application means a direction toward the optical axis and is not a direction along the optical axis. The optical axis is a central axis of the electron beam emitted from the electron gun 103 toward the sample 10 and the detector 119 in FIG. 1. As used herein, “insertable and removable in the optical axis direction” means that an object can be inserted into or removed from a position overlapping the optical axis by moving the object in a direction perpendicular or oblique to the optical axis, for example.

The cold fingers 23 and 24 can be reciprocated in the X direction (radial direction of the electron column 102) by the movable mechanism 22. The cold fingers 23 and 24 are vertically movable in the Z direction (extending direction of the electron column 102) by the movable mechanism 22.

The cold fingers 23 and 24, the sample 10, and the sample stage 3 are arranged in the X direction in a plan view. The sample 10 is placed on the sample stage 3 so as to close an upper opening (sample placement portion 3a) of a hole portion penetrating the sample stage 3 in the up-down direction in the vicinity of an end portion of the sample stage 3 extending in the X direction. As used herein, the end portion of the sample stage 3 refers to a portion including the sample placement portion (sample holder) 3a and continuously continuing in the X direction with a substantially constant thickness in the Z direction, and does not refer to a spherical portion at a tip of the sample stage 3 illustrated in FIG. 3 and a thickest portion on the opposite side. As indicated by a white arrow in FIG. 3, the sample stage 3 is axially rotatable about the extending direction (X direction) of the sample stage 3. Here, for example, the sample stage 3 can be rotated by +60 degrees. Hereinafter, tilting the sample 10 and the sample stage 3 by the axial rotation is referred to as tilting.

The cold fingers 23 and 24 are provided at a tip of the cooling unit 2. Each of the cold fingers 23 and 24 is formed of, for example, a plate-shaped metal plate extending in the X direction and having a small thickness in the Z direction. The cold finger 23 is disposed above the cold finger 24 in the Z direction. In other words, the cold finger 23 is disposed on an upstream side of the optical axis with respect to the sample stage, and the cold finger 24 is disposed on a downstream side of the optical axis with respect to the sample stage.

Each of the cold fingers 23 and 24 do not change. The cold finger 23 has an opening 31a penetrating the cold finger 23 in the Z direction. The cold finger 24 has an opening 31b and an opening 32 that penetrate the cold finger 24 in the Z direction. The openings 31b and 32 are arranged in the X direction, and the opening 32 is positioned closer to the sample stage 3 than the opening 31b.

The cold finger 23 is shorter than the cold finger 24 in the X direction, and the cold finger 24 extends to a position closer to the sample stage 3 than the cold finger 23. The openings 31a and 31b overlap each other in a plan view. The opening 32 is provided at a position not overlapping the cold finger 23 and the opening 31a in a plan view. In other words, the opening 32 is separated from the cold finger 23 and the opening 31a in a plan view. That is, the cold finger 23 or 24 is provided with a plurality of openings (openings 31a, 31b, and 32) arranged in the insertion and removal direction (x direction) for allowing the optical axis to pass therethrough in a manner that the cold finger 23 terminates closer to the movable mechanism 22 than the opening 32 in the X direction.

An interval Z1 between the cold fingers 23 and 24 in the Z direction is relatively small and is slightly larger than the thickness of the non-tilted sample stage 3 in the Z direction. The end portion of the sample stage 3 has a width larger than the thickness of the sample stage 3 in a depth direction (Y direction) of FIG. 3. The interval Z1 between the cold fingers 23 and 24 in the Z direction is smaller than the maximum length (height) in the Z direction when the end portion of the sample stage 3 is tilted by 60 degrees.

The cold fingers 23 and 24 are cooled by the liquid nitrogen contained in the dewar 21 (see FIG. 2), and their temperatures become, for example, about −196° C. When the sample 10 is observed using the transmission electron microscope 1, if contamination (foreign matter) adheres to the sample 10, the observation is hindered. As used herein, the contamination is, for example, contamination composed of molecules of hydrocarbon gas. Meanwhile, by arranging the cold fingers 23 and 24 having a low temperature in the vicinity Of the sample 10, contamination is preferentially adsorbed to the cold fingers 23 and 24, thereby obtaining a good observation result.

Next, operation examples of the cold fingers during observation will be described using Examples 1 to 3.

### Example 1

As Example 1, as illustrated in FIG. 3, an example will be described in which observation by electron beam irradiation is performed at a position where the sample 10 (sample placement portion 3a) is separated from the cold fingers 23 and 24 in a plan view. In this case, since the sample 10 (sample placement portion 3a) and the sample stage 3 are not covered with any of the cold fingers 23 and 24, the solid angle of the sample 10 is large, and the sample stage 3 can be tilted without limitation. By using image data obtained while tilting the sample, for example, a three-dimensional configuration of the sample 10 can be obtained. A part of the electron beam emitted from the electron gun 103 passes through the sample 10 and reaches the fluorescent plate 117 and the detector 119. The openings 31a, 31b, and 32 are separated from the optical axis of the electron beam.

In addition, since the sample 10 (sample placement portion 3a) is exposed, energy dispersive X-ray (EDX) analysis can also be performed. That is, the EDX analyzer performs composition analysis or the like of a sample by vertically irradiating the sample with an electron beam from above, detecting characteristic X-rays reflected over a wide range on a surface of the sample, and performing spectroscopy with energy. In FIG. 3, since there is no shield near an upper surface of the sample 10, the solid angle covering the sample 10 is large, and EDX analysis is possible. The solid angle refers to a solid angle when the EDX detector is viewed from an electron beam incident point on the sample, and the larger the value, the higher the detection efficiency.

### Example 2

As Example 2, as illustrated in FIG. 4, an example will be described in which observation by electron beam irradiation is performed in a state in which the cold fingers 23 and 24 are inserted further in the optical axis direction than in FIG. 3. Here, the sample 10 and the sample placement portion 3a overlap the opening 32 in a plan view. That is, the sample 10 and the sample placement portion 3a overlap the cold finger 24 and are exposed from the cold finger 23 in a plan view. A part of the electron beam emitted from the electron gun 103 passes through the sample 10 and the opening 32 in this order and reaches the fluorescent plate 117 and the detector 119. The openings 31a and 31b are separated from the optical axis of the electron beam.

As described above, at the position where the sample 10 is not covered by the cold finger 23, the sample 10 is close to the cold finger 24, and thus the adsorption efficiency of contamination is relatively high. Here, since the sample stage 3 is close to the cold finger 24, the tilting of the sample stage 3 is limited as compared with FIG. 3, but since the solid angle of the sample 10 is large, the EDX analysis can be performed. However, as illustrated in FIG. 5, for example, when a part of the cooling unit 2 including the cold fingers 23 and 24 is moved downward from the state illustrated in FIG. 4, the sample stage 3 can be tilted as in FIG. 3.

### Example 3

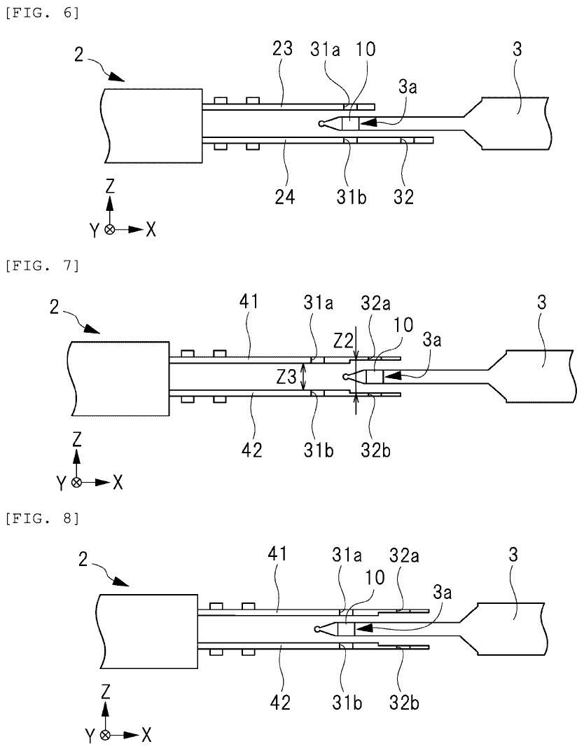

As Example 3, as illustrated in FIG. 6, an example will be described in which observation by electron beam irradiation is performed in a state in which the cold fingers 23 and 24 are further inserted in the optical axis direction than in FIG. 4 and the upper and lower sides of the sample 10 are covered by both the cold fingers 23 and 24. Here, the sample 10 and the sample placement portion 3a overlap the openings 31a and 31b in a plan view. In other words, the sample 10 and the sample placement portion 3a are sandwiched between the opening 31a and the opening 31b in the Z direction. A part of the electron beam emitted from the electron gun 103 passes through the opening 31a, the samples 10 and the opening 31b in this order and reaches the fluorescent plate 117 and the detector 119. The opening m is separated from the optical axis of the electron beam.

In this case, by arranging the cold fingers 23 and 24 in the vicinity of the sample 10, it is possible to achieve a position where the adsorption efficiency of contamination is the best among the examples illustrated in FIGS. 3 to 6. That is, from the viewpoint of the adsorption efficiency of contamination, Example 3 is superior to Example 2, and Example 2 is superior to Example 1. An angle at which the sample stage 3 can be tilted is larger in Example 1 than in Example 2, and is larger in Example 2 than in Example 3. The EDX analysis can be performed in Examples 1 and 2.

As described in Examples 1 to 3 described above, the movable mechanism 22 can open (expose) the sample placement portion 3a from either of the cold fingers 23 and 24 that is on the upstream side or the downstream side of the optical axis in a plan view.

### Effects of Present Embodiment

As an aspect of the cold finger, as illustrated in FIG. 11 as a transmission electron microscope according to a comparative example, it is conceivable to arrange a rod-shaped cold finger 25 at a position close to the sample stage 3 and perform adsorption of contamination by the cold finger 25 at a low temperature. However, with the rod-shaped cold finger 25, it is difficult to bring the cold finger 25 close to the sample 10 so as to surround the sample 10 and to adjust the solid angle of the sample 10 according to an observation mode. As a result, with the transmission electron microscope according to the comparative example, it is difficult to increase the adsorption efficiency of contamination.

Meanwhile, in the present embodiment, as illustrated in FIGS. 3 to 6, the cold fingers 23 and 24 provided with the opening portions 31a, 31b, and 32 and having different lengths are arranged in a manner of being insertable and removable in the optical axis direction. Here, by overlapping or separating the sample 10 with or from the openings 31a and 31b or the opening 32, it is easy to increase the adsorption rate of contamination, adjust the tiltable angle of the sample stage 3, and determining the feasibility of performing the EDX analysis.

In the present embodiment, by not aligning the lengths of the cold fingers 23 and 24, various observation states can be constructed according to the relative positions of the insertable and removable cold fingers 23 and 24, the sample stage 3, and the sample 10.

Here, the three patterns illustrated in FIGS. 3, 4, and 6 are described as examples. However, when focusing on the adsorption efficiency of contamination, the adsorption efficiency can be freely adjusted by adjusting the distance between the insertable and removable cold fingers 23 and 24 and the optical axis, and thus the positions of the cold fingers 23 and 24 are not limited to the positions described in the above examples.

### Embodiment 2

An aspect will be described below in which lengths of two cold fingers are aligned and a distance between the cold fingers can be changed depending on a position.

As illustrated in FIG. 7, in the present embodiment, the two cold fingers 41 and 42 have the same length in the X direction. In other words, terminal positions of the cold fingers 41 and 42 overlap each other in a plan view. The cold finger 41 has the opening 31a and an opening 32a positioned closer to the sample stage 3 than the opening 31a, and the cold finger 41 has the opening 31b and an opening 32b positioned closer to the sample stage 3 than the opening 31b. The openings 31a and 31b overlap each other in a plan view, and the openings 32a and 32b overlap each other in a plan view. As in the first embodiment, the cold fingers 41 and 42 can be inserted and removed in the optical axis direction by the movable mechanism 22.

The cold fingers 41 and 42 have a larger interval at tip sides, that is, at the positions where the openings 32a and 32b are formed, than the positions where the openings 31a and 31b are formed. That is, on a lower surface of the cold finger 41 (a surface on a cold finger 42 side), there is a step between the opening 31a and the opening 32a, and a thickness from the vicinity of the opening 32a to a terminal closer to the sample stage 3 is smaller than a thickness in the vicinity of the opening 31a. On an upper surface of the cold finger 42 (a surface on a cold finger 41 side), there is a step between the opening 31b and the opening 32b, and a thickness from the vicinity of the opening 32b to a terminal closer to the sample stage 3 is smaller than a thickness in the vicinity of the opening 31a.

That is, between the cold fingers 41 and 42, an interval Z2 in the vicinity of the openings 32a and 32b is larger than an interval Z3 in the vicinity of the openings 31a and 31b. In other words, each of the cold fingers 41 and 42 has a first region on the tip side (sample stage 3 side) in the X direction and a second region positioned on a side opposite to the sample stage 3 side with respect to the first region. The shortest interval Z3 in the Z direction between the cold fingers 41 and 42 in the second region is smaller than the shortest interval Z2 in the Z direction between the cold fingers 41 and 42 in the first region. The openings 31a and 31b are formed in the second region, and the openings 32a and 32b are formed in the first region. That is, the cold fingers 41 and 42 are thick in the regions having the openings 31a and 31b, and are thin in the regions having the openings 32a and 32b.

The interval Z2 is relatively large and is larger than the interval Z1 illustrated in FIG. 3. The interval Z3 is smaller than the interval Z2, and the interval Z1 has the same size and is slightly larger than the thickness of the non-tilted sample stage 3 in the Z direction. An end portion of the sample stage 3 has a width larger than the thickness of the sample stage 3 in a depth direction (Y direction) of FIG. 7. The interval Z3 is smaller than the maximum length (height) in the Z direction when the end portion of the sample stage 3 is tilted by 60 degrees. In this way, a plurality of regions at which the cold fingers 41 and 42 have different intervals are arranged in an insertion and removal direction (X direction). Therefore, the movable mechanism 22 can change a distance at which the sample placement portion 3a is sandwiched between the cold fingers 41 and 42.

Operation examples of the cold fingers during observation will be described below using Examples 4 and 5.

### Example 4

As Example 4, as illustrated in FIG. 7, an example will be described in which observation by electron beam irradiation is performed at a position where the sample 10 (sample placement portion 3a) overlaps the openings 32a and 32b in a plan view. A part of an electron beam emitted from the electron gun 103 passes through the opening 32a and the samples 10 and the opening 32b in this order and reaches the fluorescent plate 117 and the detector 119. The openings 31a and 31b are separated from the optical axis of the electron beam.

In this case, it is possible to tilt the sample stage 3 without limitation at a position overlapping with the opening 32a and 32b. In addition, since the cold fingers 41 and 42 are arranged in the vicinity of the sample 10, the adsorption efficiency of contamination is improved as compared with the above Examples 1 and 2.

### Example 5

As Example 5, as illustrated in FIG. 8, an example will be described in which observation by electron beam irradiation is performed at a position where the sample 10 (sample placement portion 3a) overlaps the openings 31a and 31b in a plan view. In this case, compared with FIG. 7, the cold fingers 41 and 42 are further inserted to an optical axis side (sample stage 3 side). A part of the electron beam emitted from the electron gun 103 passes through the opening 31a, the samples 10 and the opening 31b in this order and reaches the fluorescent plate 117 and the detector 119. The openings 32a and 32b are separated from the optical axis of the electron beam.

In this case, in the region having the openings 31a and 31b, since the interval Z3 at which the sample stage 3 is sandwiched is small, a tiltable angle of the sample stage 3 is limited, but by being brought closer to the cold fingers 41 and 42, the adsorption efficiency of contamination becomes optimal.

In Examples 1 to 3, the adsorption efficiency of contamination, the tiltable angle of the sample stage 3, and the limitation of EDX analysis were controlled by separating the cold fingers 23 and 24 from the optical axis. In Examples 4 and 5, in contrast to Example 3, the adsorption efficiency of contamination, the tiltable angle of the sample stage 3, and the limitation of EDX analysis are controlled by inserting the cold fingers 41 and 42 to the optical axis side. In Example 4, since the solid angle of the sample 10 is larger than that in Example 5, the detection efficiency in the EDX analysis is high.

Here, the cold fingers 41 and 42 can construct various observation states according to the positions of the sample stage 3 and the sample 10 by not aligning thicknesses of tip portions of the cold fingers 41 and 42 and the other portions.

Two patterns, Examples 4 and 5, are described here, whereas when focusing on the adsorption efficiency of contamination, the adsorption efficiency can be freely adjusted by adjusting the positions of the sample 10 and the insertable and removable cold fingers 41 and 42. Therefore, the positions of the cold fingers 41 and 42 are not limited to the positions described in the above examples.

### Embodiment 3

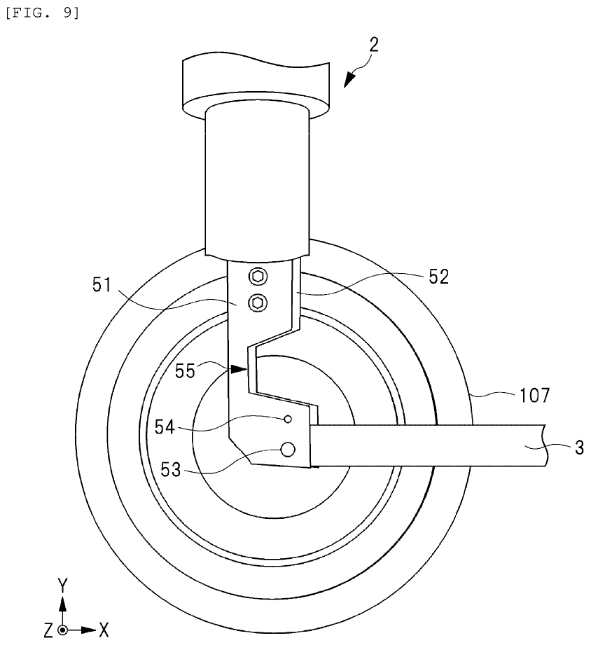

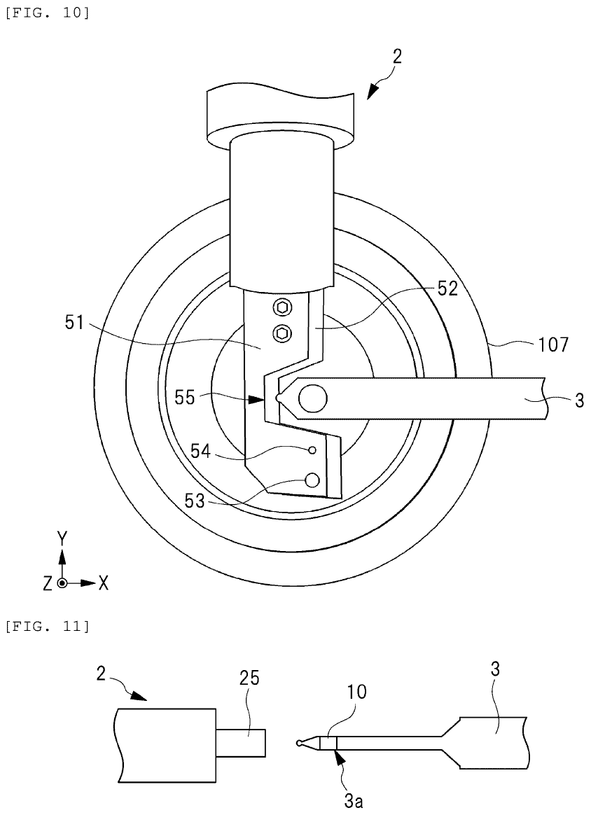

FIGS. 9 and 10 each illustrate cold fingers and the sample stage of the present embodiment. FIGS. 9 and 10 are plan views.

The insertable and removable cold fingers and the sample stage have no limitations on the angle of insertion and removal with respect to the objective lens in the electron column. FIGS. 9 and 10 each illustrate an example in which the cold fingers and the sample stage are inserted and removed perpendicularly to an extending direction (up-down direction) of the electron column. The cooling unit 2 includes a cold finger 51 that can be inserted into and removed from the electron column 102 and a cold finger 52 that can be inserted into and removed from the electron column 102.

Each of the cold fingers 51 and 52 has an opening 53 and an opening 54 having a size (diameter) different from that of the opening 53. The openings 53 and 54 are circular in a plan view. The diameter of the opening 53 is larger than the diameter of the opening 54. The openings 53 and 54 penetrate the cold fingers 51 and 52, respectively, in the Z direction. In addition, each of the cold fingers 51 and 52 has a notch (cutout processing portion) 55. The cold finger 51 is arranged on an upstream side of an optical axis with respect to the sample stage 3, and the cold finger 52 is arranged on a downstream side of the optical axis with respect to the cold finger 51 with the sample stage 3 interposed therebetween.

Here, a direction in which the cold fingers 51 and 52 are inserted and removed is the Y direction, and a direction in which the sample stage 3 is inserted and removed is the X direction. That is, the respective directions are orthogonal to each other in a plan view. Each of the cold fingers 51 and 52 has the same shape in a plan view and extends in the Y direction. Although an outline of the cold finger 51 and an outline of the cold finger 52 overlap each other in a plan view, in FIGS. 9 and 10, the relative positions of the cold fingers 51 and 52 in a plan view are shifted from each other for easy understanding of the drawings.

Centers of the circular openings 53 and 54 of the cold finger 51 are arranged in the Y direction. The same applies to the cold finger 52. In a plan view, the opening 53 of the cold finger 51 and the opening 53 of the cold finger 52 overlap each other, and the opening 54 of the cold finger 51 and the opening 54 of the cold finger 52 overlap each other.

In a plan view, the notch 55 is provided on one side surface side of the cold finger 51 in a lateral direction (X direction). In a plan view, the notch 55 is provided on a side surface of the cold finger 51 on which the sample stage 3 is inserted into the electron column 102. The cold finger 52 is also provided with the notch 55 at the same position as the cold finger 51. In the cooling unit 2, the notches 55, the openings 54, and the openings 53 are arranged toward a tip side of the cold fingers 51 and 52 in the Y direction in order from a movable mechanism 22 side (the side on which the cold fingers 51 and 52 are supported).

FIGS. 9 and 10 do not illustrate the openings 53 and 54 of the cold finger 52 shielded by the cold finger 51. FIG. 9 does not illustrate the sample 10 shielded by the cold finger 51.

### Example 6

In FIG. 9, the sample stage 3 is covered with the cold fingers 51 and 52. Therefore, the adsorption efficiency of contamination is highest. A part of an electron beam emitted from the electron gun 103 sequentially passes through, for example, the opening 53 of the cold finger 51, the sample 10, and the opening 53 of the cold finger 52, and reaches the fluorescent plate 117 and the detector 119. The opening 54 and the notch 55 are separated from the optical axis of the electron beam.

Here, the case in which the opening 53 and the sample 10 overlap each other is described as an example, but the opening 54 may overlap the sample 10. It is also possible to improve the contrast for cutting scattered electrons by selecting one of the opening portions 53 and 54 having different hole diameters as the opening portion overlapping the sample 10. That is, when a plurality of openings are arranged in the insertion and removal direction, the contrast of a formed image can be changed by changing the opening through which the optical axis passes to any of the plurality of openings by the movable mechanism 22.

### Example 7

As illustrated in FIG. 10, the sample stage 3 and the sample 10 can be arranged in the notch 55 by further inserting the cold fingers 51 and 52 to an optical axis side as compared with FIG. 9. That is, in a plan view, the sample stage 3 and the sample 10 are positioned in the notch 55 and are separated from the cold fingers 51 and 52. In other words, the sample stage 3 and the sample 10 do not overlap the cold fingers 51 and 52.

At this position, while maintaining a state in which the adsorption efficiency implemented by the cold fingers 51 and 52 is high, there is no limitation on the tilting of the sample, and analysis by EDX is also possible. That is, since the sample 10 is surrounded by the cold fingers 51 and 52 in a total of three directions on both sides in the Y direction and one side in the X direction in a plan view, the adsorption efficiency of contamination is high. Further, since the sample 10 and the sample stage 3 are exposed from the cold fingers 51 and 52 in a plan view, the sample stage 3 can be tilted, and since the solid angle is large, analysis by EDX is also possible.

Further, it is also possible to improve the contrast for cutting scattered electrons by selecting one of the opening portions 53 and 54 having different hole diameters as the opening portion overlapping the sample 10.

Although the invention made by the present inventors has been specifically described above based on the embodiments, the invention is not limited to the embodiments, and various modifications can be made without departing from the gist of the invention. For example, the embodiments described above have been described in detail to facilitate understanding of the technical content, and the disclosure is not necessarily limited to those including all the configurations described above. A part of a configuration of a certain example can be replaced with a configuration of another example, and a configuration of another example can be added to a configuration of a certain example. A part of a configuration in each example may be added to, deleted from, or replaced with another configuration.

### INDUSTRIAL APPLICABILITY

The invention can be widely used to an electron microscope.

### REFERENCE SIGNS LIST

1: transmission electron microscope
2: cooling unit
3: sample stage
3a: sample placement portion
10: sample
11: computer
21: dewar
22: movable mechanism
23, 24, 25, 41, 42, 51, 52: cold finger
31a, 31b, 32, 32a, 32b, 53, 54: opening
102: electron column
103: electron gun
104: gun valve
105: condenser lens
107: objective lens
110: intermediate lens
111: projection lens
112: intermediate chamber
113: sample chamber
115: observation chamber
117: fluorescent plate
118: fluorescent plate detector array
119: detector

1. An electron microscope comprising:
a sample stage;
a first cold finger arranged on an upstream side of an optical axis with respect to the sample stage;
a second cold finger arranged on a downstream side of the optical axis with respect to the first cold finger with the sample stage interposed therebetween; and
a movable mechanism configured to move the first cold finger and the second cold finger in an insertion and removal direction with respect to the optical axis, wherein
the movable mechanism is configured to change a solid angle at which a sample placement portion of the sample stage is covered by one or both of the first cold finger and the second cold finger.

2. The electron microscope according to claim 1, wherein
the first cold finger or the second cold finger is provided with
a plurality of openings arranged in the insertion and removal direction for allowing the optical axis to pass therethrough.

3. The electron microscope according to claim 1, wherein
lengths of the first cold finger and the second cold finger in the insertion and removal direction are different from each other, and
the movable mechanism is configured to expose the sample placement portion from either of the cold fingers that is on the upstream side or the downstream side of the optical axis in a plan view.

4. The electron microscope according to claim 1, wherein
a plurality of regions at which the first cold finger and the second cold finger have different intervals are arranged in the insertion and removal direction, and
the movable mechanism is configured to change a distance at which the sample placement portion is sandwiched between the first cold finger and the second cold finger.

5. The electron microscope according to claim 2, wherein
the movable mechanism is configured to change an contrast of a formed image by changing an opening through which the optical axis passes to any of the plurality of openings.
